(19) United States
(12) Patent Application Publication
(10) Pub. No.: US 2023/0317526 A1
(43) Pub. Date: Oct. 5, 2023

(54) METHOD TO FORM SEMICONDUCTOR DEVICE AND SEMICONDUCTOR DEVICE THEREOF

(71) Applicant: HeFeChip Corporation Limited, Hong Kong (HK)

(72) Inventors: LIANG LI, Guilderland, NY (US); Chun Yu Wong, Clifton Park, NY (US); John Zhang, Altamont, NY (US); HUANG LIU, Mechanicville, NY (US); Sunil Singh, Mechanicville, NY (US); Heng Yang, Rexford, NY (US)

(21) Appl. No.: 17/657,835

(22) Filed: Apr. 4, 2022

(51) Int. Cl. H01L 21/84; H01L 27/12

(52) U.S. Cl. CPC H01L 21/845; H01L 27/1211

(57) ABSTRACT

The present invention proposes a semiconductor device. The semiconductor device includes a first and a second transistor sets, a fin pattern, a rare earth oxide layer and an insulation layer. The first and a second transistor sets commonly have at the bases thereof a buried oxide layer (BOX), wherein the first transistor set has a rare earth oxide. The fin pattern on the BOX within a first region for the first transistor set and a second region for the second transistor set. The rare earth oxide layer includes the rare earth oxide and is formed on the BOX and the fin pattern in the first region. The insulation layer is formed on the rare earth oxide layer in the first region, the BOX and the fin pattern in the second region.

### TECHNICAL FIELD

Embodiments of the present disclosure are related to a method to form a semiconductor device, and more particularly, are related to a method to form stable and multiple threshold voltage transistors for a volatile memory.

### BACKGROUND

When the complementary metal oxide semiconductor (CMOS) devices go into sub-45 nm scale, a metal gate electrode together with a high dielectric constant or a high-k insulator is considered necessary as one of the critical technologies because there are some concerns about the conventional poly-Si electrode and Si oxynitride dielectrics stack. Those concerns are as follows: 1. Poly-depletion effect to add an equivalent oxide thickness (EOT) or EOT up to ˜0.5 nm to the gate stack, which is a significant portion for the overall targeted EOT requirement of ˜1 nm; 2. Excess gate leakage when the EOT of the gate stack is reduced to sub-1 nm; and 3. High resistance for the poly electrode. Therefore, the additional benefit of using metal gate/high-k dielectrics is due to the improvement of the device variability as no poly-Si doping is needed.

Lanthanum oxide can be a good material as a metal gate. Although lanthanum oxide and dielectric capping incorporation into the Hf-based host high-k dielectrics is demonstrated as a practical solution to achieve a low threshold-voltage VT or metal-gated uni-channel nMOSFETs fabricated using a gate-first flow, multiple stack layers such as LaO/wet etch stop layer/sacrificial layer/capping layer cause complicated processes, expensive costs, threshold voltage shifts and unstable threshold voltages. In addition, complicated stack layers can cause undesired undercut causing threshold voltage shifts while etching.

Therefore, it is an expectation to have a simple process and structure including different types of transistors having different threshold voltages, and it can prevent threshold voltage shifting and keep the threshold voltages stable at the same time.

### SUMMARY OF INVENTION

In view of the drawbacks in the above-mentioned prior art, the present invention proposes a method to form a semiconductor device including a first and a second transistor sets commonly having at the bases thereof a buried oxide layer (BOX), wherein the first transistor set has a rare earth oxide. The method comprises steps of: forming a fin pattern on the BOX within a first region for the first transistor set and a second region for the second transistor set; sequentially forming an insulation layer on the fin pattern, a first capping layer on the insulation layer and a first protective layer on the first capping layer; disposing a first mask on the first protective layer in the second region; removing the first capping layer and the first protective layer in the first region; removing the first protective layer in the second region; disposing a rare earth oxide layer on the insulation layer in the first region and the first capping layer in the second region; and disposing a second capping layer on the rare earth oxide layer.

In accordance with one embodiment of the present disclosure, the present invention proposes a method to form a semiconductor device including a first and a second transistor sets commonly having at the bases thereof a buried oxide layer (BOX), wherein the first transistor set has a rare earth oxide. The method comprises steps of: forming a fin pattern on the BOX within a first region for the first transistor set and a second region for the second transistor set; sequentially forming an insulation layer on the fin pattern, a rare earth oxide layer on the insulation layer, a first capping layer on the rare earth oxide layer and a first protective layer on the first capping layer; disposing a first mask in the first region; and removing the first protective layer, the first capping layer, the rare earth oxide layer and the insulation layer in the second region.

In accordance with another embodiment of the present disclosure, the present invention proposes a semiconductor device. The semiconductor device comprises a first and a second transistor sets, a fin pattern, a rare earth oxide layer and an insulation layer. The first and a second transistor sets commonly have at the bases thereof a buried oxide layer (BOX), wherein the first transistor set has a rare earth oxide. The fin pattern on the BOX within a first region for the first transistor set and a second region for the second transistor set. The rare earth oxide layer includes the rare earth oxide and is formed on the BOX and the fin pattern in the first region. The insulation layer is formed on the rare earth oxide layer in the first region, the BOX and the fin pattern in the second region.

The above embodiments and advantages of the present invention will become more readily apparent to those ordinarily skilled in the art after reviewing the following detailed descriptions and accompanying drawings:

### BRIEF DESCRIPTION OF THE DRAWINGS

FIGS. 1A-1E are schematic diagrams showing a method to form a semiconductor device according to a preferred embodiment of the present disclosure;

FIGS. 1F-1G are schematic diagrams showing another method to form a semiconductor device according to a preferred embodiment of the present disclosure;

FIGS. 1F′-1I′ are schematic diagrams showing alternative method to form a semiconductor device according to a preferred embodiment of the present disclosure;

FIGS. 2A-2C are schematic diagrams showing a schematic diagram showing a method to form the semiconductor device according to another preferred embodiment of the present disclosure;

FIGS. 2D-2G are schematic diagrams showing another method to form a semiconductor device according to another preferred embodiment of the present disclosure; and

FIG. 3 is a schematic diagram showing a semiconductor device according to a preferred embodiment of the present disclosure.

### DETAILED DESCRIPTION OF THE PREFERRED EMBODIMENTS

Please refer to all FIGS. of the present invention when reading the following detailed description, wherein all FIGS. of the present invention demonstrate different embodiments of the present invention by showing examples, and help the skilled person in the art to understand how to implement the present invention. The present examples provide sufficient embodiments to demonstrate the spirit of the present invention, each embodiment does not conflict with the others, and new embodiments can be implemented through an arbitrary combination thereof, i.e., the present invention is not restricted to the embodiments disclosed in the present specification.

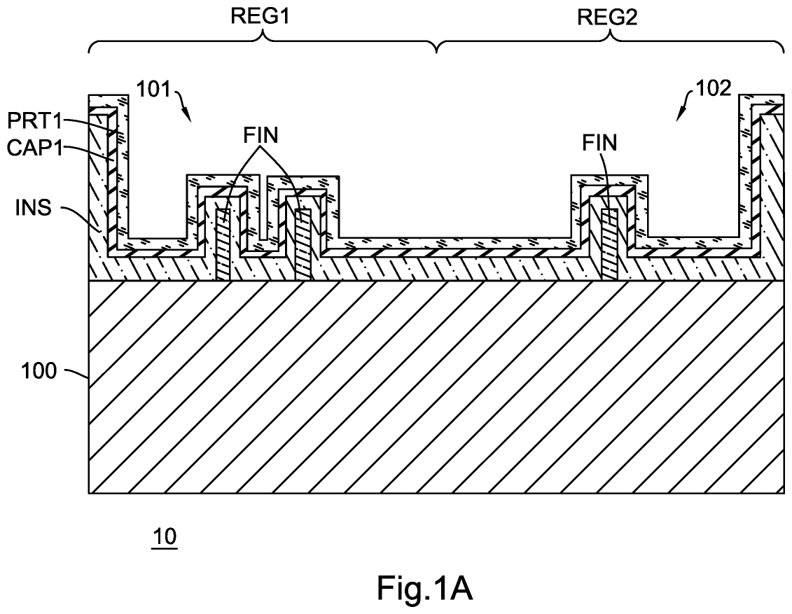

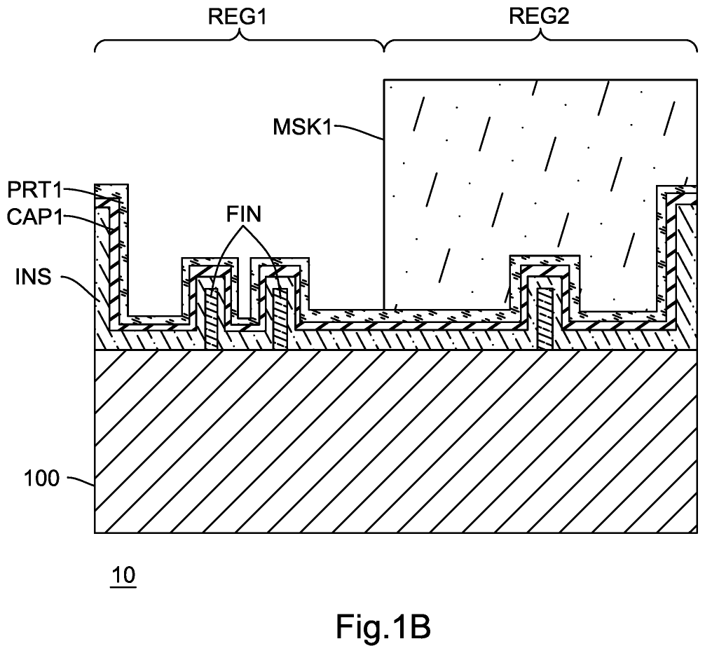

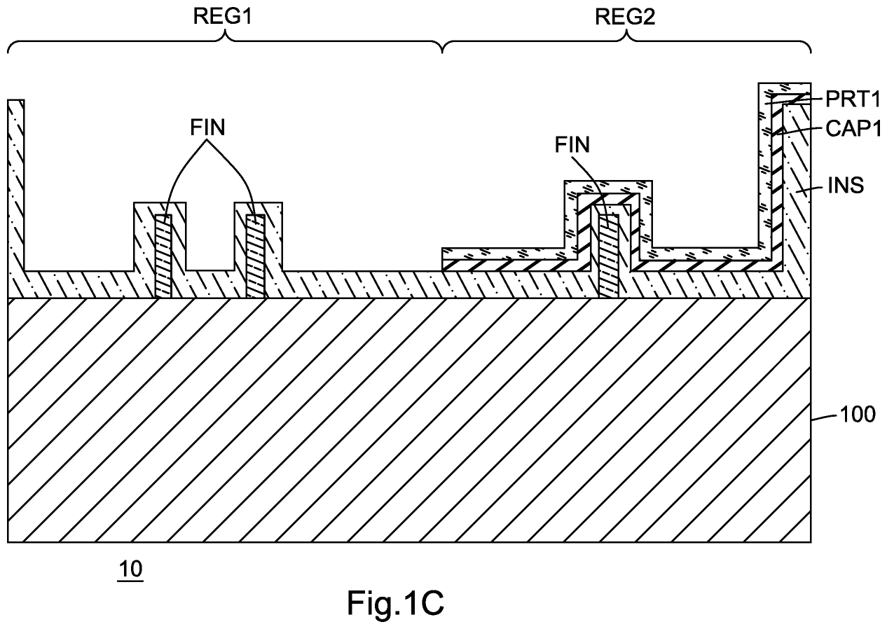

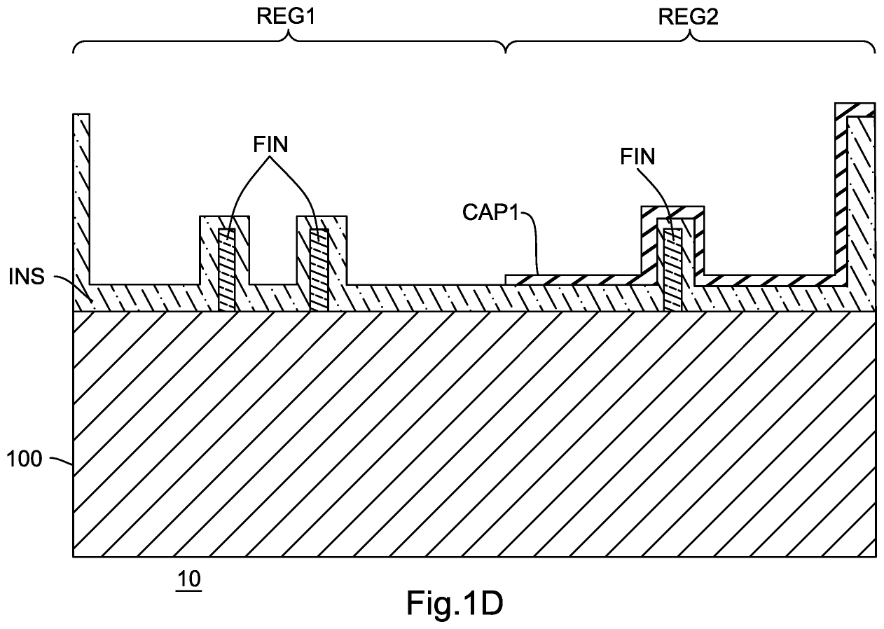

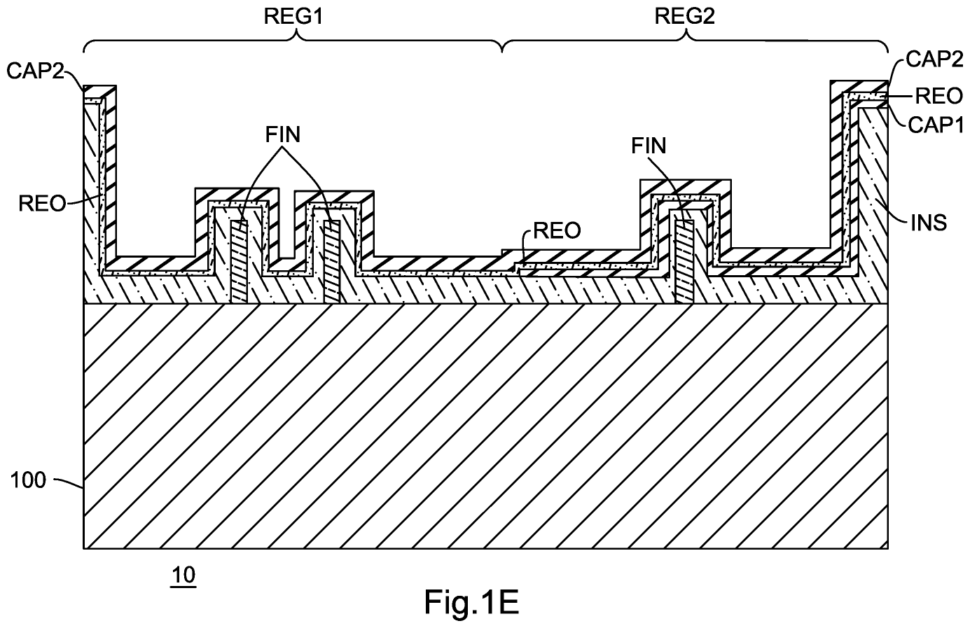

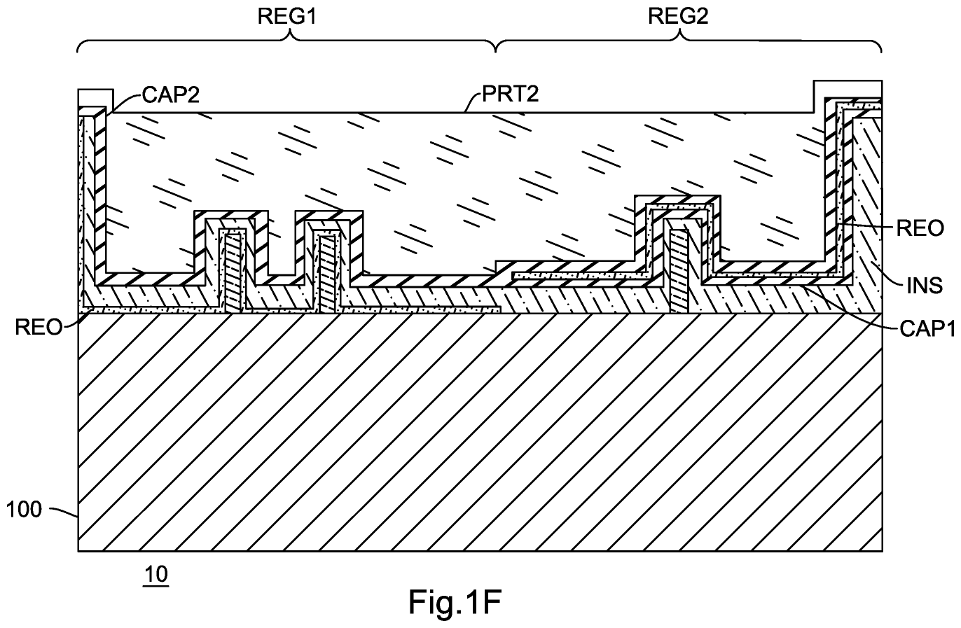

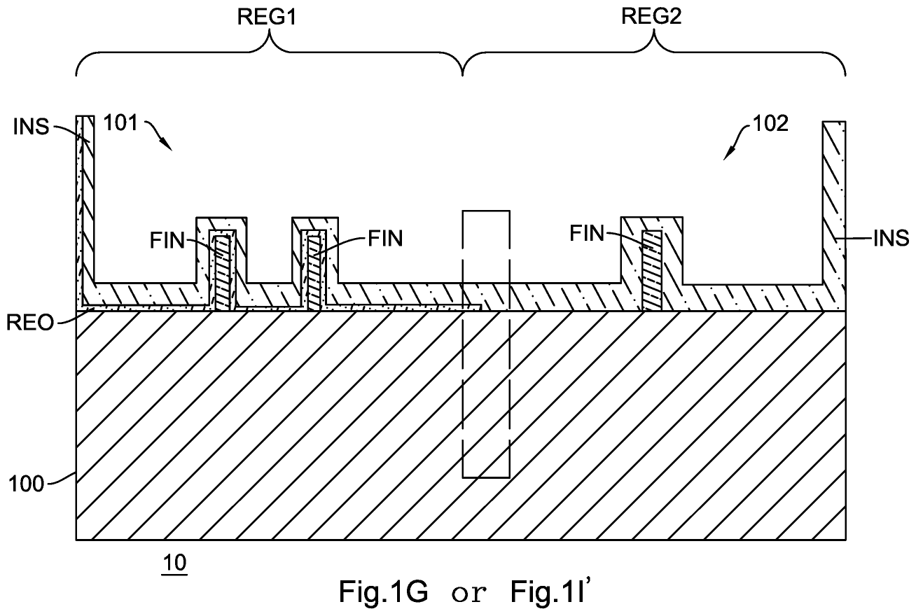

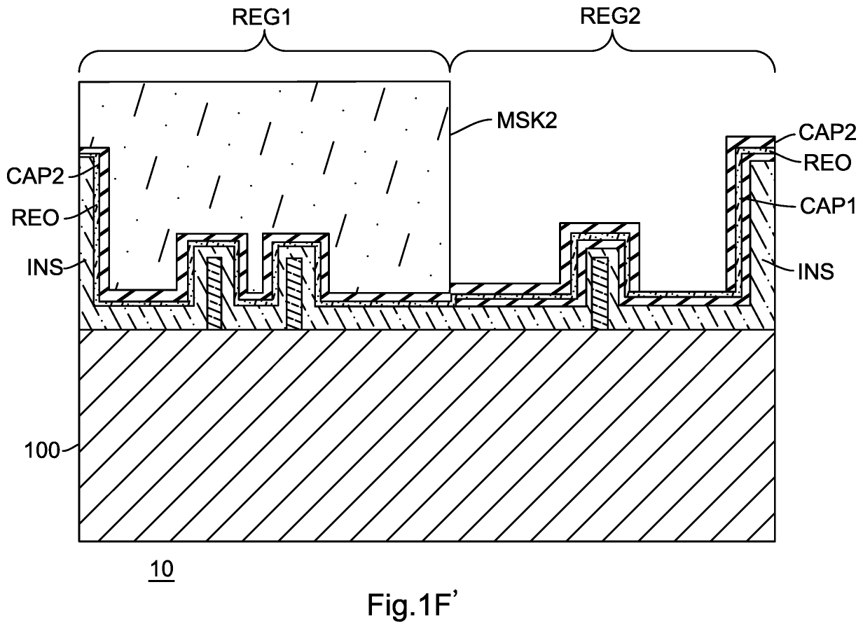

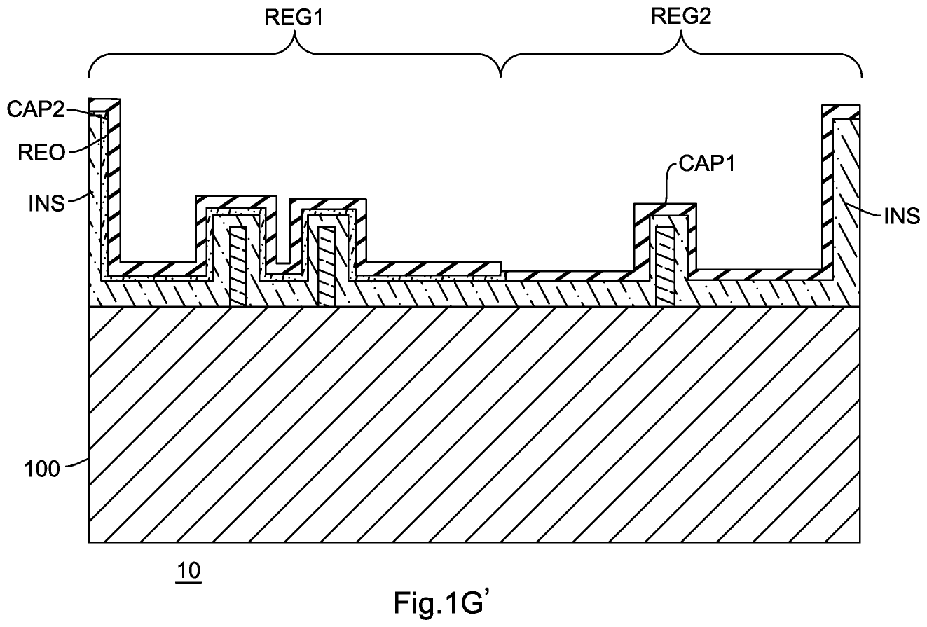

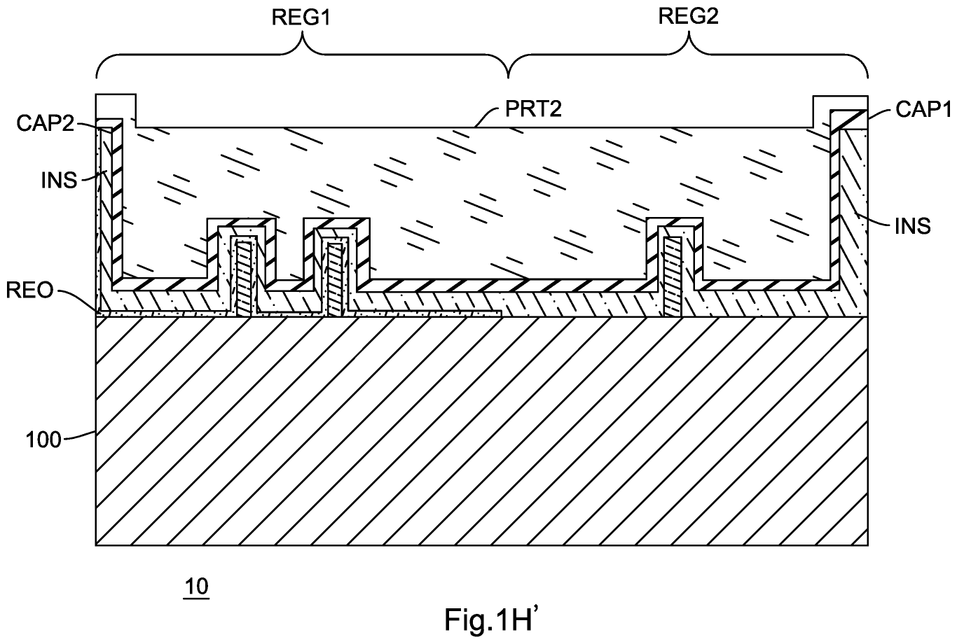

Please refer to FIGS. 1A-1E, which are schematic diagrams showing a method S10 to form a semiconductor device 10 including a first and a second transistor sets 101, 102 commonly having at the bases thereof a buried oxide layer (BOX) 100 according to a preferred embodiment of the present disclosure. The first transistor set 101 has a rare earth oxide REO. The method S10 includes the following steps: As shown in FIG. 1A, a fin pattern FIN is formed on the BOX 100 within a first region REG1 for the first transistor set 101 and a second region REG2 for the second transistor set 102. As shown in FIG. 1A, an insulation layer INS on the fin pattern FIN, a first capping layer CAP1 on the insulation layer INS and a first protective layer PRT1 on the first capping layer CAP1 are sequentially formed. As shown in FIG. 1B, a first mask MSK1 is disposed on the first protective layer PRT1 in the second region REG2. As shown in FIG. 1C, the first capping layer CAP1 and the first protective layer PRT1 in the first region REG1 are removed. As shown in FIG. 1D, the first protective layer PRT1 in the second region REG2 is removed. As shown in FIG. 1E, a rare earth oxide layer REO is disposed on the insulation layer INS in the first region REG1 and the first capping layer CAP1 in the second region REG2. In addition, as shown in FIG. 1E, a second capping layer CAP2 is disposed on the rare earth oxide layer REO.

In any one of the embodiments of the present disclosure, the insulation layer INS is a high k material layer including an HfO2. The first and second capping layers CAP1, CAP2 are TiN layers. The first and second protective layers PRT1, PRT2 are amorphous silicon layers. The rare earth oxide layer REO includes a lanthanide oxide layer LaO.

In any one of the embodiments of the present disclosure, the step of removing the first capping layer CAP1 and the first protective layer PRT1 in the first region REG1 is performed through a first wet etching process. The step of removing the first protective layer PRT1 in the second region REG2 is performed through a second wet etching process. The method further includes the following steps: For example, as shown in FIG. 1F, a second protective layer PRT2 is disposed on the second capping layer CAP2, wherein the first and the second protective layers PRT1, PRT2 are amorphous silicon layers. For example, as shown in FIG. 1F, annealing is performed to drive the rare earth oxide layer REO into the insulation layer INS in the first region REG1, while the second capping layer CAP2 in the second region REG2 prevents the rare earth oxide layer REO from being driven into the insulation layer INS in the second region REG2. In addition, for example, as shown in FIG. 1G, the second protective layer PRT2, the second capping layer CAP2 in the first and the second region REG1, REG2, the rare earth oxide layer REO in the second region REG2 and the first capping layer CAP1 in the second region REG2 are removed through a third wet etching process.

In an alternative embodiment to form the semiconductor device 10, as shown in FIG. 1F′ following FIG. 1E, the method further includes the following steps: A second mask MSK2 is disposed on the second capping layer CAP2 in the first region REG1. As shown in FIG. 1G′, removing the second capping layer CAP2, and the rare earth oxide layer REO in the second region REG2 are removed. As shown in FIG. 1H′, a second protective layer PRT2 is disposed on the second capping layer CAP2 in the first region REG1 and the first capping layer CAP1 in the second region REG2. As shown in FIG. 1H′, annealing is performed to drive the rare earth oxide layer REO into the insulation layer INS in the first region REG1. In addition, as shown in FIG. 1I′, the second protective layer PRT2 and the second capping layer CAP2 in the first region REG1, and the first capping layer CAP1 in the second region REG2 are removed through a third wet etching process.

In any one of the embodiments of the present disclosure, the first, the second and the third wet etching processes are performed by using one of an NH4OH, a standard cleaning for micro particles and a Tetraethylammonium hydroxide (TEAH).

In any one of the embodiments of the present disclosure, the first and the second protective layers PRT1, PRT2 are wet etched by the NH4OH or the TEAH; and the first and the second capping layers are wet etched by the standard cleaning for micro particles.

In any one of the embodiments of the present disclosure, a temperature range for annealing to drive the rare earth oxide layer REO into the insulation layer INS is 400 to 800 degrees Celsius.

In any one of the embodiments of the present disclosure, the rare earth oxide layer's thickness ranges from 5 to 30 Å The insulation layer's thickness ranges from 3 to 12 nm. The first and second capping layers' thicknesses range from 1 to 3 nm. The first and second protective layers' thicknesses range from 3 to 12 nm.

Please refer to FIG. 1G or 1I′. The semiconductor device 10 completed has only the rare earth oxide layer REO on the BOX 100 and the fin FIN in the first region REG1, the insulation layer INS on the rare earth oxide layer REO in the first region REG1, which is a simple structure to prevent threshold voltage from shifting. Therefore, it overcomes the unstable threshold voltage resulting from complicated or multiple layers.

In any one of the embodiments of the present disclosure, the BOX layer 100 includes a silicon oxide layer. The first transistor set 101 includes a first n-type finFET and a first p-type finFET. The second transistor set 102 includes a second n-type finFET and a second p-type finFET. The first n-type finFET, the first p-type finFET, the second n-type finFET and the second p-type finFET provide multiple threshold voltages therebetween. For example, if the thickness of the rare earth oxide layer REO increases in the first transistor set 101, the threshold voltage of the n-type finFET in the first transistor set 101 reduces, and the threshold voltage of the p-type finFET in the first transistor set 101 increases, and vice versa.

In any one of the embodiments of the present disclosure, for example, the semiconductor device 10 is used for SRAM but is not limited thereto. The first transistor set 101 includes the rare earth oxide layer REO and the insulation layer INS thereon. The second transistor set 102 includes the insulation layer INS. Both the first and the second transistor sets 101, 102 provide stable threshold voltages.

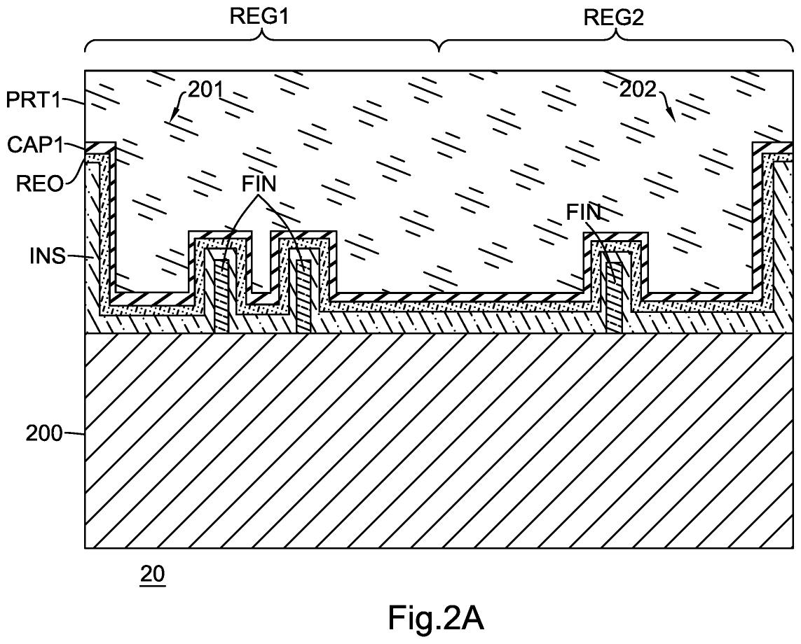

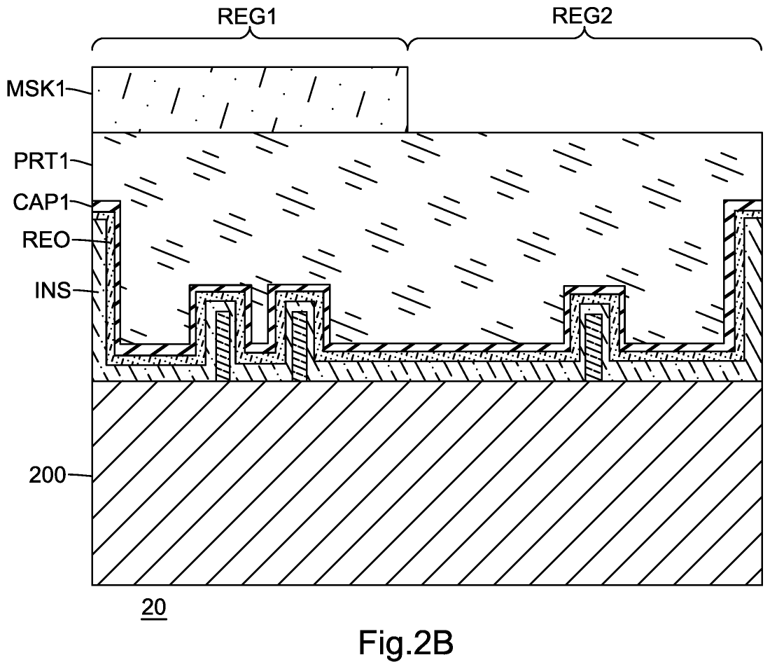

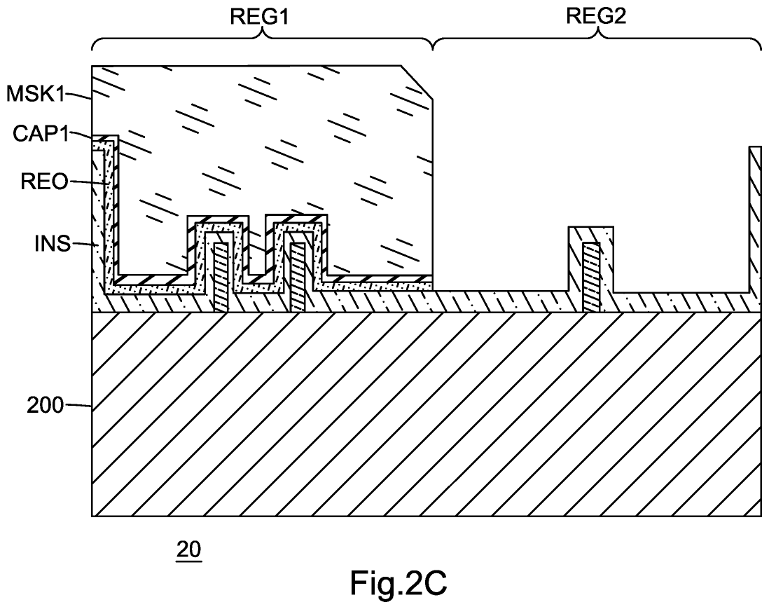

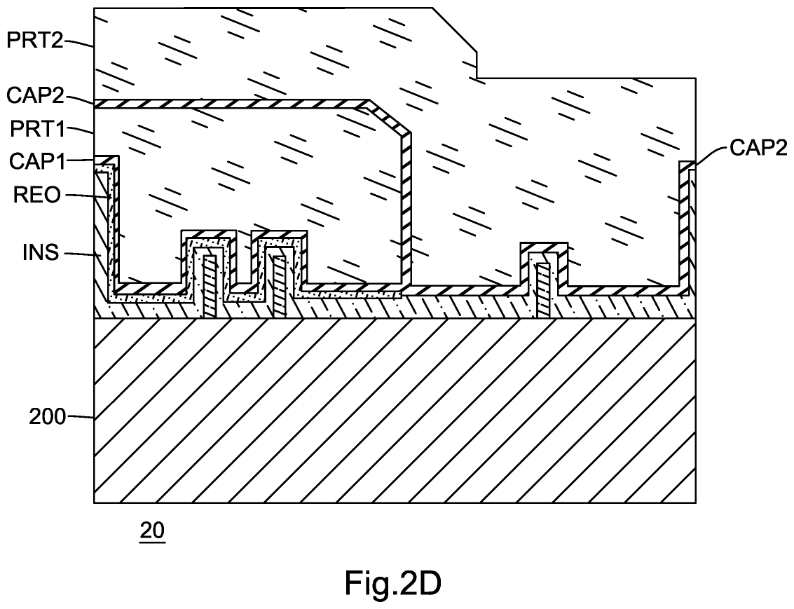

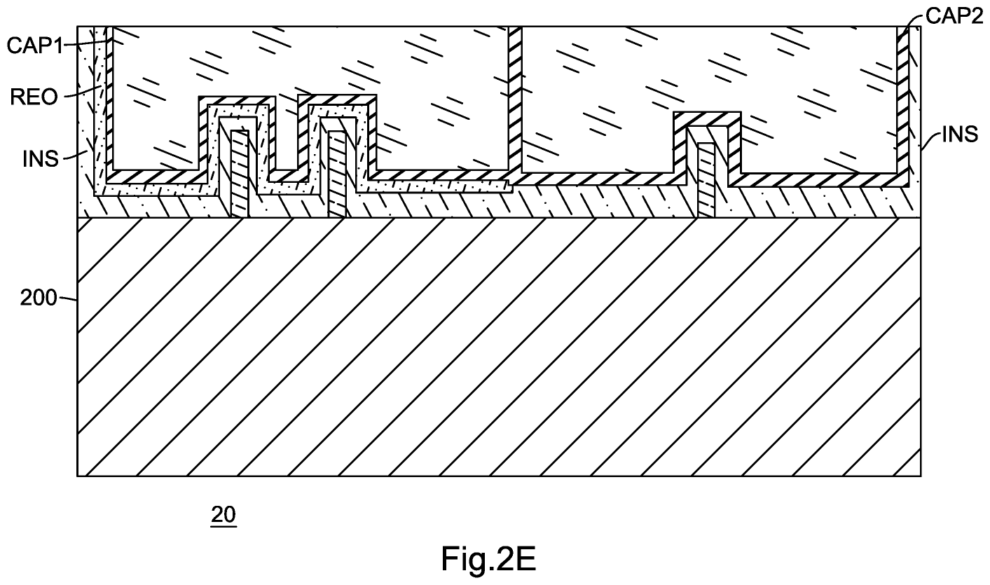

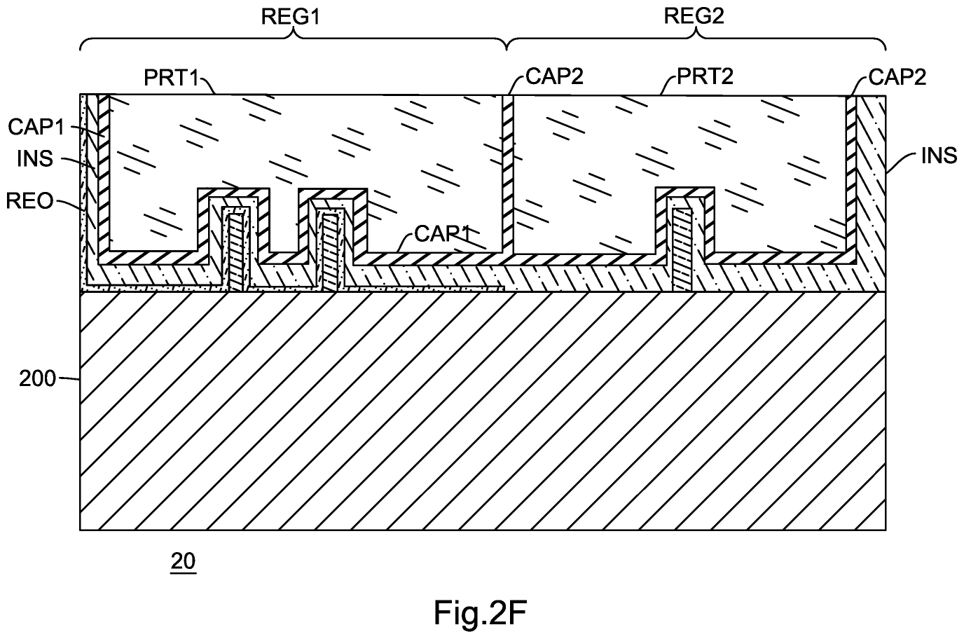

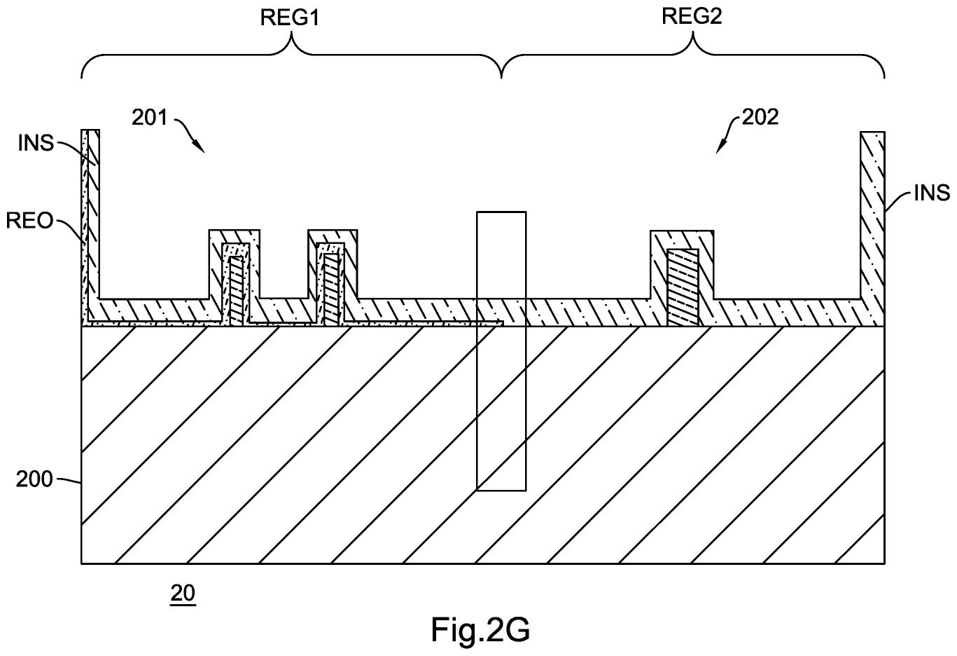

Please refer to FIGS. 2A-2C, which are schematic diagrams showing a method S20 to form the semiconductor device 20 including a first and a second transistor sets 201, 202 commonly having at the bases thereof a buried oxide layer (BOX) 200 according to another preferred embodiment of the present disclosure. The first transistor set 201 has a rare earth oxide. The method S20 includes the following steps: As shown in FIG. 2A, a fin pattern FIN is formed on the BOX 200 within a first region REG1 for the first transistor set 201 and a second region 202 for the second transistor set 202. As shown in FIG. 2A, an insulation layer INS on the fin pattern FIN, a rare earth oxide layer REO on the insulation layer INS, a first capping layer CAP1 on the rare earth oxide layer REO and a first protective layer PRT1 on the first capping layer CAP1 are sequentially formed. As shown in FIG. 2B, a first mask MSK1 is disposed in the first region REG1. In addition, As shown in FIG. 2C, removing the first protective layer PRT1, the first capping layer CAP1, the rare earth oxide layer REO and the insulation layer INS in the second region REG2 are removed.

In any one of the embodiments of the present disclosure, the method S20 further includes the following step: For example, as shown in FIG. 2D, a second capping layer CAP2 is disposed on the first protective layer PRT1 in the first region REG1 and on the insulation layer INS in the second region REG2. For example, as shown in FIG. 2D, a second protective layer PRT2 is disposed on the second capping layer CAP2 in the first and the second regions REG1, REG2. In addition, for example, as shown in FIG. 2E, polishing the second protective layer PRT2 is performed and is stopped on the first protective layer PRT1 in the first region REG1 through a chemical-mechanical process.

In any one of the embodiments of the present disclosure, the method S20 further includes the following steps: For example, as shown in FIG. 2F, annealing is performed to drive the rare earth oxide layer REO into the insulation layer INS in the first region REG1. In addition, for example, as shown in FIG. 2G, the first protective layer PRT1 in the first region REG1 and the second protective layer PRT2 in the second region REG2, and the first capping layer CAP1 in the first region REG1 and the second capping layer CAP2 in the second region REG2 are removed through a third wet etching process. For example, the third wet etching process is a non-selective wet etching process by the TEAH and/or H2O2.

Please refer to FIG. 2G. The first transistor set 201 in the first region REG1 with the rare earth oxide layer REO does not overlap the second transistor set 202 in the second region REG2 without the rare earth oxide layer REO. Thus, the unstable threshold voltage or the threshold voltage shifting issues resulting from complex overlapping stack layers between the first transistor set 201 with the rare earth oxide layer REO and the second transistor set 202 without the rare earth oxide layer REO can be overcome.

In any one of the embodiments of the present disclosure, the insulation layer INS is a high k material layer including an HfO2. The first and the second capping layers CAP1, CAP2 are TiN layers. The first and the second protective layers PRT1, PRT2 are amorphous silicon layers. The rare earth oxide layer REO includes a lanthanide oxide layer.

In any one of the embodiments of the present disclosure, the first and the third wet etching processes are performed by using one of an NH4OH, a standard cleaning for micro particles and a TEAH. The first and the second protective layers PRT1, PRT2 are wet etched by the NH4OH or the TEAH. The first and the second capping layers CAP1, CAP2 are wet etched by the standard cleaning for micro particles. A temperature range for annealing to drive the rare earth oxide layer REO into the insulation layer INS is from 400 to 800 degrees Celsius. The rare earth oxide layer's thickness ranges from 5 to 30 Å. The insulation layer's thickness ranges from 3 to 12 nm. The first and the second capping layers' thicknesses range from 1 to 3 nm. The first and the second protective layers' thicknesses range from 3 to 12 nm. The BOX layer 100, 200 includes a silicon oxide layer.

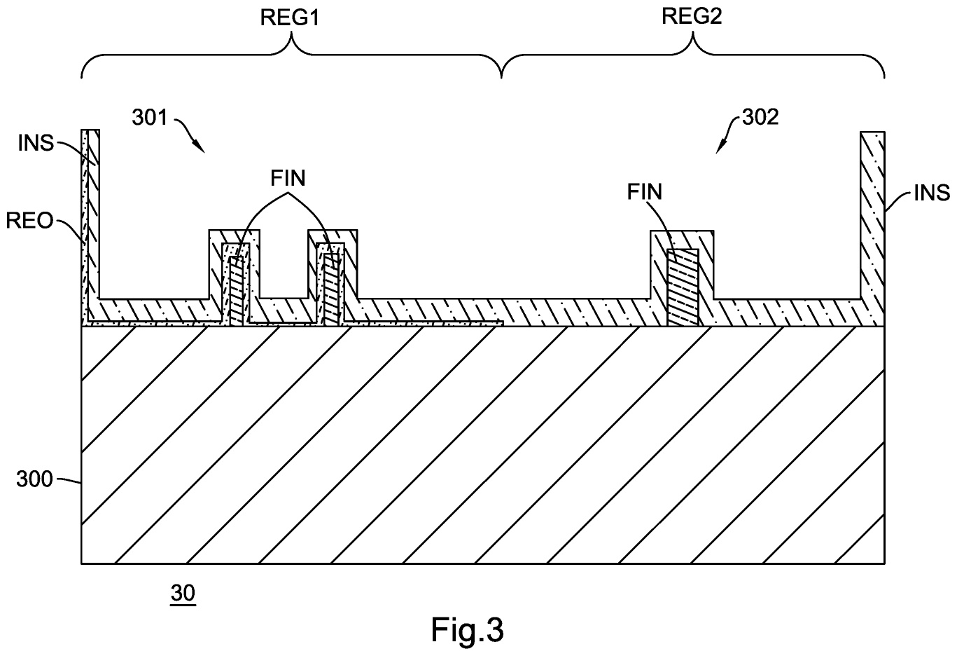

Please refer to FIG. 3, which is a schematic diagram showing a semiconductor device 30 according to a preferred embodiment of the present disclosure. The semiconductor device 30 includes a first and a second transistor sets 301, 302, a fin pattern FIN, a rare earth oxide layer REO and an insulation layer INS. The first and a second transistor sets 301, 302 commonly have at the bases thereof a buried oxide layer (BOX) 300, wherein the first transistor set 301 has a rare earth oxide. The fin pattern FIN on the BOX 300 within a first region REG1 for the first transistor set 301 and a second region REG2 for the second transistor set 302. The rare earth oxide layer REO includes the rare earth oxide and is formed on the BOX 300 and the fin pattern FIN in the first regionREG1. The insulation layer INS is formed on the rare earth oxide layer REO in the first region REG1, the BOX 300 and the fin pattern FIN in the second region REG2.

In any one of the embodiments of the present disclosure, the BOX layer 300 includes a silicon oxide layer. The first transistor set 301 includes a first n-type finFET and a first p-type finFET. The second transistor set 302 includes a second n-type finFET and a second p-type finFET. The first n-type finFET, the first p-type finFET, the second n-type finFET and the second p-type finFET provide multiple threshold voltages therebetween.

In any one of the embodiments of the present disclosure, for example, the semiconductor device 30 is used for SRAM but is not limited thereto. The first transistor set 301 includes the rare earth oxide layer REO and the insulation layer INS thereon. The second transistor set 302 includes the insulation layer INS. Both the first and the second transistor sets 301, 302 provide stable threshold voltages.

In any one of the embodiments of the present disclosure, the rare earth oxide layer's thickness ranges from 5 to 30 Å. The insulation layer's thickness ranges from 3 to 12 nm.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A method to form a semiconductor device including a first and a second transistor sets commonly having at the bases thereof a buried oxide layer (BOX), wherein the first transistor set has a rare earth oxide and the method comprises steps of:
forming a fin pattern on the BOX within a first region for the first transistor set and a second region for the second transistor set;
sequentially forming an insulation layer on the fin pattern, a first capping layer on the insulation layer and a first protective layer on the first capping layer;
disposing a first mask on the first protective layer in the second region;
removing the first capping layer and the first protective layer in the first region;
removing the first protective layer in the second region;
disposing a rare earth oxide layer on the insulation layer in the first region and the first capping layer in the second region; and
disposing a second capping layer on the rare earth oxide layer.

2. The method as claimed in claim 1, wherein:
the insulation layer is a high k material layer including an HfO2;
the first and second capping layers are TiN layers;
the first and second protective layers are amorphous silicon layers; and
the rare earth oxide layer includes a lanthanide oxide layer.

3. The method as claimed in claim 1, wherein:
the step of removing the first capping layer and the first protective layer in the first region is performed through a first wet etching process;
the step of removing the first protective layer in the second region is performed through a second wet etching process;
the method further comprises steps of:
disposing a second protective layer on the second capping layer, wherein the first and the second protective layers are amorphous silicon layers;
annealing to drive the rare earth oxide layer into the insulation layer in the first region, while the second capping layer in the second region prevents the rare earth oxide layer from being driven into the insulation layer in the second region; and
removing the second protective layer, the second capping layer in the first and the second regions, the rare earth oxide layer in the second region and the first capping layer in the second region through a third wet etching process.

4. The method as claimed in claim 3, wherein:
the first, the second and the third wet etching processes are performed by using one of an NH₄OH, a standard cleaning for micro particles and a Tetraethylammonium hydroxide (TEAH).

5. The method as claimed in claim 4, wherein:
the first and the second protective layers are wet etched by the NH₄OH or the TEAH; and
the first and the second capping layers are wet etched by the standard cleaning for micro particles.

6. The method as claimed in claim 3, wherein a temperature range for annealing to drive the rare earth oxide layer into the insulation layer is 400 to 800 degrees Celsius.

7. The method as claimed in claim 3, wherein:
the rare earth oxide layer's thickness ranges from 5 to 30 Å;
the insulation layer's thickness ranges from 3 to 12 nm;
the first and second capping layers' thicknesses range from 1 to 3 nm; and
the first and second protective layers' thicknesses range from 3 to 12 nm.

8. The method as claimed in claim 1, wherein:
the BOX layer includes a silicon oxide layer;
the first transistor set includes a first n-type finFET and a first p-type finFET;
the second transistor set includes a second n-type finFET and a second p-type finFET; and
the first n-type finFET, the first p-type finFET, the second n-type finFET and the second p-type finFET provide multiple threshold voltages therebetween.

9. The method as claimed in claim 1, wherein:
the first transistor set includes the rare earth oxide layer and the insulation layer thereon, the second transistor set includes the insulation layer, and both the first and the second transistor sets provide stable threshold voltages.

10. The method as claimed in claim 1, further comprises steps of:
disposing a second mask on the second capping layer in the first region;
removing the second capping layer, and the rare earth oxide layer in the second region;
disposing a second protective layer on the second capping layer in the first region and the first capping layer in the second region;
annealing to drive the rare earth oxide layer into the insulation layer in the first region; and
removing the second protective layer and the second capping layer in the first region, and the first capping layer in the second region through a third wet etching process.

11. A method to form a semiconductor device including a first and a second transistor sets commonly having at the bases thereof a buried oxide layer (BOX), wherein the first transistor set has a rare earth oxide and the method comprises steps of:
forming a fin pattern on the BOX within a first region for the first transistor set and a second region for the second transistor set;
sequentially forming an insulation layer on the fin pattern, a rare earth oxide layer on the insulation layer, a first capping layer on the rare earth oxide layer and a first protective layer on the first capping layer;
disposing a first mask in the first region; and
removing the first protective layer, the first capping layer, the rare earth oxide layer and the insulation layer in the second region.

12. The method as claimed in claim 11, further comprises step of:
removing the first protective layer, the first capping layer, the rare earth oxide layer and the insulation layer in the second region through a first wet etching process.

13. The method as claimed in claim 12, further comprises step of:
disposing a second capping layer on the first protective layer in the first region and on the insulation layer in the second region;
disposing a second protective layer on the second capping layer in the first and the second regions; and
polishing the second protective layer and stopping on the first protective layer in the first region through a chemical-mechanical process.

14. The method as claimed in claim 13, further comprises steps of:
annealing to drive the rare earth oxide layer into the insulation layer in the first region; and
removing the first protective layer in the first region and the second protective layer in the second region, and the first capping layer in the first region and the second capping layer in the second region through a third wet etching process.

15. The method as claimed in claim 14, wherein:
the insulation layer is a high k material layer including an HfO2;
the first and the second capping layers are TiN layers;
the first and the second protective layers are amorphous silicon layers; and
the rare earth oxide layer includes a lanthanide oxide layer.

16. The method as claimed in claim 11, wherein:
the first and the third wet etching processes are performed by using one of an NH₄OH, a standard cleaning for micro particles and a TEAH;
the first and the second protective layers are wet etched by the NH₄OH or the TEAH;
the first and the second capping layers are wet etched by the standard cleaning for micro particles.
a temperature range for annealing to drive the rare earth oxide layer into the insulation layer is from 400 to 800 degrees Celsius;
the rare earth oxide layer's thickness ranges from 5 to 30 Å;
the insulation layer's thickness ranges from 3 to 12 nm;
the first and the second capping layers' thicknesses range from 1 to 3 nm;
the first and the second protective layers' thicknesses range from 3 to 12 nm; and
the BOX layer includes a silicon oxide layer.

17. A semiconductor device comprising:
a first and a second transistor sets commonly having at the bases thereof a buried oxide layer (BOX), wherein the first transistor set has a rare earth oxide;
a fin pattern on the BOX within a first region for the first transistor set and a second region for the second transistor set;
a rare earth oxide layer including the rare earth oxide and formed on the BOX and the fin pattern in the first region; and
an insulation layer formed on the rare earth oxide layer in the first region, the BOX and the fin pattern in the second region.

18. The semiconductor device as claimed in claim 17, wherein:
the BOX layer includes a silicon oxide layer;
the first transistor set includes a first n-type finFET and a first p-type finFET;
the second transistor set includes a second n-type finFET and a second p-type finFET; and
the first n-type finFET, the first p-type finFET, the second n-type finFET and the second p-type finFET provide multiple threshold voltages therebetween.

19. The semiconductor device as claimed in claim 17, wherein:
the first transistor set includes the rare earth oxide layer and the insulation layer thereon, the second transistor set includes the insulation layer, and both the first and the second transistor sets provide stable threshold voltages.

20. The semiconductor device as claimed in claim 17, wherein:
the rare earth oxide layer's thickness ranges from 5 to 30 Å; and
the insulation layer's thickness ranges from 3 to 12 nm.
